(19) United States
(12) Patent Application Publication
(10) Pub. No.: US 2015/0040829 A1
(43) Pub. Date: Feb. 12, 2015

(54) MULTIZONE HOLLOW CATHODE DISCHARGE SYSTEM WITH COAXIAL AND AZIMUTHAL SYMMETRY AND WITH CONSISTENT CENTRAL TRIGGER

(71) Applicant: APPLIED MATERIALS, INC., Santa Clara, CA (US)

(72) Inventors: Kartik RAMASWAMY, San Jose, CA (US); Andrew NGUYEN, San Jose, CA (US); Sergey G. BELOSTOTSKIY, Sunnyvale, CA (US)

(73) Assignee: APPLIED MATERIALS, INC., Santa Clara, CA (US)

(21) Appl. No.: 14/026,921

(22) Filed: Sep. 13, 2013

Related U.S. Application Data
(60) Provisional application No. 61/864,970, filed on Aug. 12, 2013.

(51) Int. Cl. H01J 37/32

(52) U.S. Cl. CPC H01J 37/32596
USPC 118/723 E; 313/231.31

(57) ABSTRACT

Embodiments of the present invention relate to hollow cathode plasma sources with improved uniformity. One embodiment of the present invention provides a hollow cathode assembly having a conductive rod disposed in an inner volume along a central axis of a hollow cathode. The conductive rod being closest to the ground electrode and having the sharpest features of the hollow cathode becomes the point of plasma ignition. Since the conductive rod is positioned along the central axis, the plasma is ignited at symmetrically about the central axis thus improving plasma uniformity and reducing skews.

### CROSS-REFERENCE TO RELATED APPLICATIONS

This application claims priority to U.S. Provisional Patent Application Ser. No. 61/864,970, filed on Aug. 12, 2013, which herein is incorporated by reference.

### BACKGROUND

1. Field

Embodiments of the present invention generally relate to apparatus and methods for semiconductor processing. More particularly, embodiments of the present invention relate to apparatus and methods for generating plasma or electron beams in a hollow cathode system.

2. Description of the Related Art

Hollow cathode discharge plasma and electron beam sources are used in semiconductor processing. Generally, a hollow cathode plasma source includes a cathode having an inner volume and a ground anode spaced apart from the cathode facing the inner volume. During operation, molecular gases are introduced to the inner volume of the cathode while a RF power is applied between the cathode and the ground electrode to create radicals from the molecular gas.

Traditional hollow cathode plasma sources include a hollow cathode having a smaller diameter and a ground electrode having a larger diameter. The size difference between the cathode and the ground electrode creates non-uniformly in the generated plasma, causing non-uniformity and/or non-symmetry in processing.

Therefore, there is a need for a hollow cathode plasma source with improved uniformity and symmetry.

### SUMMARY

Embodiments of the present invention generally relate to apparatus and methods for improving process uniformity and reducing skews in semiconductor processing. More particularly, embodiments of the present invention relate to hollow cathode plasma sources with improved uniformity.

One embodiment of the present invention provides an electrode for generating a plasma. The electrode includes a conductive body having an upper side, a lower side, and a central volume open at the lower side. The conductive body and the central volume is substantially symmetric about a central axis extending from the upper side to the lower side. A gas channel is formed in the conductive body and open to the central volume. The electrode further includes a conductive rod at least partially disposed in the central volume along the central axis. A first end of the conductive rod is coupled to the conductive body and a second end extends out of the central volume beyond the lower side.

Another embodiment of the present invention provides a hollow cathode plasma source. The hollow cathode plasma source includes a first electrode comprising a conductive body having an upper side, a lower side, and a central volume open at the lower side, wherein the conductive body and the central volume is substantially symmetric about a central axis extending from the upper side to the lower side, and a gas channel is formed in the conductive body and open to the central volume, and a conductive rod at least partially disposed in the central volume along the central axis, wherein a first end of the conductive rod is coupled to the conductive body and a second end extends out of the central volume beyond the lower side. The hollow cathode plasma source also includes a second electrode facing the lower side of the first electrode, wherein the second electrode includes a plurality of through holes in fluid connection with the central opening of the first electrode, and an RF isolator disposed between the first electrode and second electrode.

Yet another embodiment of the present invention provides a hollow cathode plasma source including an RF return shield secured coaxially to and symmetrically about electrodes of the hollow cathode plasma source providing a RF returning path.

Another embodiment of the present invention provides an apparatus for processing semiconductor substrate. The apparatus includes a chamber body defining an inner volume, a hollow cathode plasma source disposed above the inner volume, and a substrate support assembly disposed below the hollow cathode plasma source. The hollow cathode plasma source includes a first electrode, a second electrode and an RF isolator disposed between the first electrode and second electrode. The first electrode includes a conductive body having an upper side, a lower side, and a central volume open at the lower side, wherein the conductive body and the central volume is substantially symmetric about a central axis extending from the upper side to the lower side, and a gas channel is formed in the conductive body and open to the central volume, and a conductive rod at least partially disposed in the central volume along the central axis, wherein a first end of the conductive rod is coupled to the conductive body and a second end extends out of the central volume beyond the lower side. The second electrode facing the lower side of the first electrode, wherein the second electrode includes a plurality of through holes in fluid connection with the central opening of the first electrode.

Yet another embodiment of the present invention provides a method for generating a plasma. The method includes flowing one or more processing gas to a central volume of a conductive body through a gas channel formed in the conductive body. The conductive body and the central volume is substantially symmetric about a central axis extending from the upper side to the lower side. The method also includes applying an RF power between a ground electrode disposed opposing the conductive body and a conductive rod at least partially disposed in the central volume along the central axis. A first end of the conductive rod is coupled to the conductive body and a second end extends out of the central volume beyond the lower side towards the ground electrode.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a plasma processing chamber according to one embodiment of the present invention.

FIG. 2A is a schematic perspective sectional view of an electrode assembly according to one embodiment of the present invention.

FIGS. 2B-2D are schematic partial sectional views of electrode assemblies according to embodiments of the present invention.

FIG. 3A is a schematic perspective sectional view of an electrode assembly according to one embodiment of the present invention.

FIG. 3B is a partial sectional view showing gas outlets of the electrode assembly of FIG. 3A.

FIGS. 3C-3E are partial sectional views of conductive rods having various end sections according to embodiments of the present invention.

FIG. 4A is a perspective view of a RF return shield assembly according to one embodiment of the present invention.

FIG. 4B is a sectional view of the RF return shield assembly of FIG. 4A.

FIG. 5A is a schematic sectional side view of a hollow cathode assembly according to one embodiment of the present invention.

FIG. 5B is a schematic perspective view of a ground electrode according to one embodiment of the present invention.

FIG. 5C is a schematic perspective sectional view of an outer electrode of the hollow cathode assembly of FIG. 5A.

FIG. 6 is a schematic top view of a hollow cathode assembly according to another embodiment of the present invention.

FIG. 7 is a schematic sectional side view of a hollow cathode assembly according to one embodiment of the present invention.

FIG. 8 is a schematic sectional side view of a hollow cathode assembly according to another embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to apparatus and methods for improving process uniformity and reducing skews in semiconductor processing. More particularly, embodiments of the present invention relate to hollow cathode plasma sources with improved uniformity.

One embodiment of the present invention provides a hollow cathode assembly having a conductive rod disposed in an inner volume along a central axis of a hollow cathode. The conductive rod being closest to the ground electrode and having the sharpest features of the hollow cathode becomes the point of plasma ignition. Since the conductive rod is positioned along the central axis, the plasma is ignited at symmetrically about the central axis thus improving plasma uniformity and reducing skews.

In another embodiment of the present invention, one or more processing gas is supplied to the inner volume of the hollow cathode in a substantially symmetrical manner. For example, a gas channel formed in the hollow cathode may have a plurality of outlets symmetrically disposed around the conductive rod, thus, uniformly and symmetrically delivering the one or more processing gas to the inner volume of the hollow cathode.

Another embodiment of the present invention provides a hollow cathode plasma source having a symmetric multizone hollow cathode. Each of the multiple zones can be powered independently. Process gas can also be independently delivered to each one of the multiple zones. The symmetric multizone hollow cathode improves uniformity and reduces processing skew.

In another embodiment of the present invention, a ground shield assembly that enclosing the hollow cathode is provided to further improve symmetry of the hollow cathode plasma source. The ground shield assembly forms a symmetric and closed shield around the hollow cathode, thus, further improving symmetry.

Embodiments of the present invention provide a center to edge plasma uniformity by providing two independent concentric hollow cathodes. Embodiments of the present invention provide a repeatable discharge origin site in the center of the hollow cathode in the form of a central rod and/or raised ground electrode. Additionally, the presence of the central rod also functions as a baffle enabling uniform gas distribution.

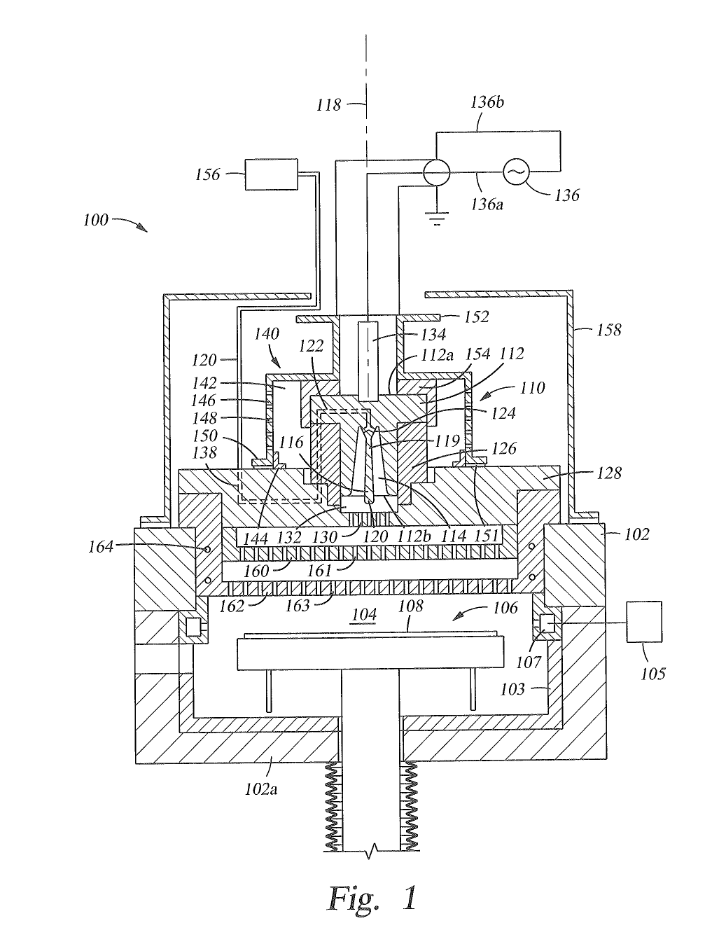

FIG. 1 is a schematic sectional view of a plasma processing chamber 100 according to one embodiment of the present invention. The plasma processing chamber 100 includes a hollow cathode plasma source 110 according to embodiments of the present invention with improved symmetry and uniformity.

The plasma processing chamber 100 generally includes a chamber body 102 and a liner 103 disposed in inside the chamber body 102. The liner 103 defines a chamber volume 104 for substrate processing. A substrate support assembly 106 is disposed in the chamber volume 104 to support a substrate 108 to be processed. An exhaust plenum 107 may be formed in the liner 103 and connected with a vacuum pump 105 to maintain a low pressured process environment during operation. Alternatively, the vacuum pump 105 may be connected to a vacuum port formed on a bottom 102a of the chamber body 102. The vacuum port may be formed off center from the substrate support assembly 106 or concentrically around the substrate support assembly 106.

The hollow cathode plasma source 110 is disposed above the chamber body 102 for supplying processing gas in plasma phase and/or molecular phase to the chamber volume 104. The hollow cathode plasma source 110 includes a hollow cathode assembly 112, a ground electrode 128 and an isolator 126 disposed between the hollow cathode assembly 112 and the ground electrode 128.

The hollow cathode assembly 112 may be formed from a RF conductive material and have an inner volume 114 which serves as plasma cavity during plasma generation. The hollow cathode assembly 112 has an upper side 112a and a lower side 112b. A central axis 118 extends from the upper side 112a to the lower side 112b. The hollow cathode assembly 112 and the inner volume 114 may be symmetric about the central axis 118. The inner volume 114 opens at the lower side 112b and creates a plasma cavity between the hollow cathode assembly 112 and the ground electrode 128. In one embodiment, cross sections of the inner volume 114 may be expanding towards the lower side 112b. The expanding inner volume 114 provides distance gradient between the hollow cathode assembly 112 and the ground electrode 128 which helps control the formation and stability of the plasma generated in the plasma cavity.

A central rod 116, formed from a RF conductive material, is coupled to the hollow cathode assembly 112. The central rod 116 is disposed along the central axis 118. An upper end 119 of the central rod 116 is coupled to the hollow cathode assembly 112 inside the inner volume 114. A lower end 120 of the central rod 116 extends along the central axis 118 out of the inner volume 114 towards the ground electrode 128. By extending out of the inner volume 114, the lower end 120 of the central rod 116 is the closest to the ground electrode 128 compared with other portions of the hollow cathode assembly 112, and as a result, plasma always ignites at the lower end of the central rod 116. The hollow cathode plasma source 110 enables symmetrical plasma ignition because the central rod 116 is disposed along the central axis 118.

A gas channel 122 is formed in the hollow cathode assembly 112 for delivering one or more processing gas to the inner volume 114 of the hollow cathode assembly 112. According to one embodiment, the gas channel 122 includes a plurality of outlets 124 formed around the upper end 119 of the central rod 116. The plurality of outlets 124 may be evenly distributed about the central axis 118 and the central rod 116 so that processing gas may be delivered to the inner volume 114 in a uniform and symmetrical manner.

The ground electrode 128 may be a conductive plate having a recess 132 along the central axis 118 for receiving the isolator 126 and the hollow cathode assembly 112. A plurality of through holes 130 may be formed through the ground electrode 128 to allow the plasma formed in the inner volume 114 to enter the chamber volume 104 for processing.

In one embodiment, a RF connector 134 may be attached to the hollow cathode assembly 112 from the upper side 112a. The RF connector 134 may be disposed along the central axis 118 to provide electrical symmetry with a central RF feed configuration. The RF connector 134 may be coupled to a RF output 136a of a RF power source 136 so that the hollow cathode assembly 112 is RF hot during operation.

The plasma processing chamber 100 further includes a RF ground shield assembly 140 that encloses the hollow cathode assembly 112 and the RF connector 134. During operation, a RF ground 136b of the RF power source 136 may be connected to the RF ground shield assembly 140. The RF ground shield assembly 140 forms a symmetric shell around the hollow cathode assembly 112 to provide a symmetric RF return path for the hollow cathode plasma source 110. The symmetric shell formed by the RF ground shield assembly 140 may also be continuous to improve uniformity of RF return path.

In one embodiment, the RF ground shield assembly 140 may form a cylindrical shell defining an enclosed volume 142 in which the hollow cathode assembly 112 and the RF connector 134 are disposed. The RF ground shield assembly 140 may include a contact ring 144 secured to the ground electrode 128. A perforated tube 146 may extend above the contact ring 144 and in electrical connection with the contact ring 144. The perforated tube 146 may have a plurality of openings 148 formed therethrough. The plurality of openings 148 are designed the enable heat convection therethrough without allowing RF leak. In one embodiment, the size of the plurality of openings 148 may be selected to enable heat convection and prevent RF leaking. The perforated tube 146 may include a flange 150 for symmetrically aligning the perforated tube 146 with the hollow cathode assembly 112. However, a gap 151 may be present between the ground electrode 128 and the perforated tube 146 so that the perforated tube 146 are not in direct contact with the ground electrode 128. The gap 151 allows room for thermal expansion caused during operation while enabling the flange 150 to contact the contact ring 144 to establish a RF return path. In one embodiment, an upper tube 152 may be attached to the perforated tube 146. The upper tube 152 may be smaller in diameter than the perforated tube 146 for surrounding the RF connector 134.

In one embodiment, an isolator 154 may be disposed between the RF ground shield assembly 140 and the hollow cathode assembly 112 within the enclosed volume 142. The isolator 154 may be positioned so that the RF hot hollow cathode assembly 112 is not in the line of sight of the RF ground shield assembly 140 to prevent unwanted arcing.

In one embodiment, a gas channel 138 may be formed in the ground electrode 128 and the isolator 126. The gas channel 138 connects with the gas channel 122 in the hollow cathode assembly 112 with a gas source 156 to provide one or more processing gas to the inner volume 114. In one embodiment, the gas channel 138 may open at a location radially outward the RF ground shield assembly 140 so that regions inside the RF ground shield assembly 140 can be symmetrical and uniform to improve RF symmetry.

An outer shell 158 may be disposed over the chamber body 102 to shield the hollow cathode plasma source 110 from any external noises, such as magnetic noises. In one embodiment, the outer shell 158 may be formed from a material having high magnetic permeability, such as mu-metal.

A blocker plate 160 having a plurality of openings 161 may be attached to ground electrode 128 to enable uniform distribution of plasma generated in the inner volume 114. A showerhead 162 having a plurality of gas openings 163 may be disposed below the blocker plate 160 to uniformly distribute gas passing through the blocker plate 160 into the chamber volume 104. In one embodiment, the showerhead 162 may have heating/cooling channels 164 formed therein for temperature control.

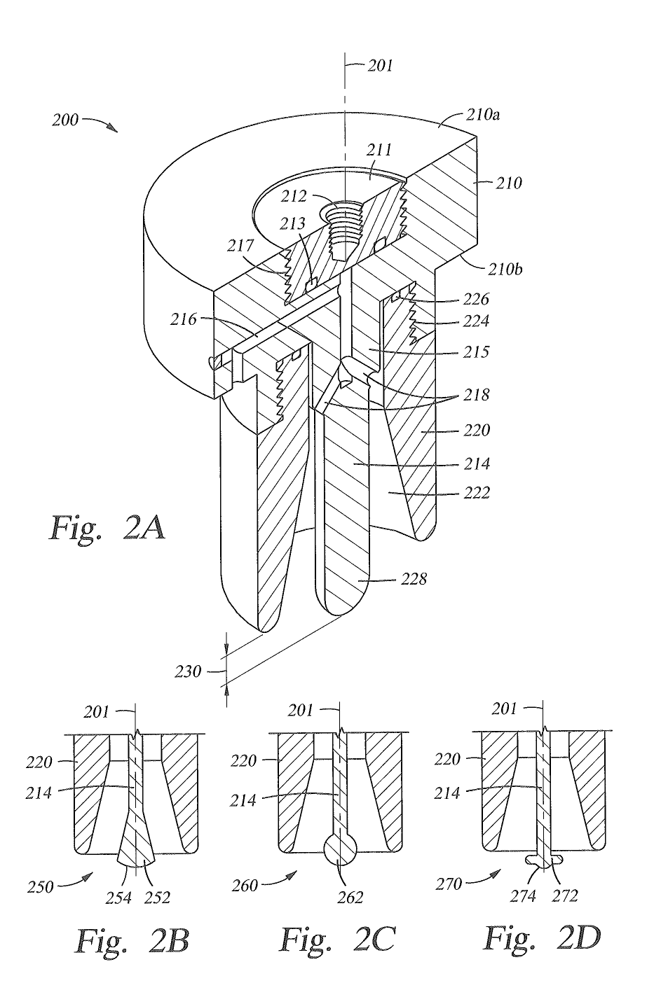

FIG. 2A is a schematic perspective sectional view of a hollow cathode assembly 200 according to one embodiment of the present invention. The hollow cathode assembly 200 may be used as the hollow cathode assembly 112 in the plasma processing chamber 100 of FIG. 1.

The hollow cathode assembly 200 may include a base portion 210 that is symmetrical about a central axis 201. The base portion 210 may be a disk shaped conductive body having an upper side 210a and a lower side 210b. An RF adapting structure 212 may be formed on the upper side 210a along the central axis 201. In one embodiment, the RF adapting structure 212 may be a threaded blind hole. The RF adapting structure 212 facilitate connection of the hollow cathode assembly 200 to a RF power supply. A central rod 214 may extend from the lower side 210b of the base portion 210 along the central axis 201. A gas channel 216 is formed in the base portion 210. The gas channel 216 may include several linear sections that can be formed from drilling. In one embodiment, the gas channel 216 may include a plurality of outlets 218 formed at an upper end 215 of the central axis 201. In one embodiment, the plurality of outlets 218 may be symmetrically arranged about the central axis 201 to provides symmetrical gas distribution.

To facilitate manufacturing of the gas channel 216, the base portion 210 may include an upper recess 217 formed on the upper side 210a so that a portion of the gas channel 216 on the central axis 201 may be drilled from a bottom of the upper recess 217. The RF adapting structure 212 may be formed in an upper plug 211 disposed in the upper recess 217. The upper plug 211 may be coupled to the base portion 210 by threads. An RF seal 213, such as an o-ring seal, may be disposed between the upper plug 211 and the base portion 210 to prevent any gas leak from the gas channel 216.

The hollow cathode assembly 200 further includes a tubular portion 220 coupled to the base portion 210 at the lower side 210b. The tubular portion 220 may be attached to the base portion 210 at a joint 224. The tubular portion 220 and the base portion 210 form an inner volume 222 which is symmetrical about the central axis 201. In one embodiment, the joint 224 may be a threaded joint that ensures good RF connection between the base portion 210 and tubular portion 220. A RF seal 226 may be disposed between the base portion 210 and the tubular portion 220. The RF seal 226 prevents any plasma formed in the inner volume 222 from escaping through the contact area of the base portion 210 and the tubular portion 220.

The inner volume 222 may be expanding from the base portion 210 towards a tip 228 of the central rod 214. The tip 228 of the central rod 214 extends below and outside the tubular portion 220 by a distance 230. During operation, the tip 228 is positioned at the closest point to an opposite electrode, such as the ground electrode 128 in FIG. 1, thus becoming the point of plasma ignition. Because the tip 228 of the central rod 214 is positioned on the central axis 201 about which the hollow cathode assembly 200 is symmetric, the plasma ignites in a symmetrical manner. The distance 230 may be selected in accordance with processing requirements.

The shape of the tip 228 may be designed differently to achieve desired ignition effect. In FIG. 2A, the tip 228 has a semi-spherical shape having the same diameter as the central rod 214.

In other embodiments, the tip of the central rod 214 may have different shapes, for example as shown in FIGS. 2B-2D. The tip of the central rod 214 may have a lowest point at the central axis 201 to ensure symmetrical plasma ignition. FIG. 2B is a partial sectional view of a hollow cathode assembly 250, similar to the hollow cathode assembly 200, wherein a tip 252 of the central rod 214 has a cone shape. The tip 252 expands from the central axis 201 and ends with a convex bottom surface 254. The surface 254 may be symmetrical to the central axis 201 of the central rod 214 to have the lowest point on the central axis 201. FIG. 2C is a partial sectional view of a hollow cathode assembly 260, similar to the hollow cathode assembly 200, wherein a tip 262 of the central rod 214 has a spherical shape. FIG. 2D is a partial sectional view of a hollow cathode assembly 270, similar to the hollow cathode assembly 200, wherein a tip 272 of the central rod 214 has a disk shape. The tip 272 has a blunt tip 274 at the central axis 201 to serve as a focal point for plasma ignition. The tip 272 may be machined to form radius at sharp corners to avoid any unwanted sparks.

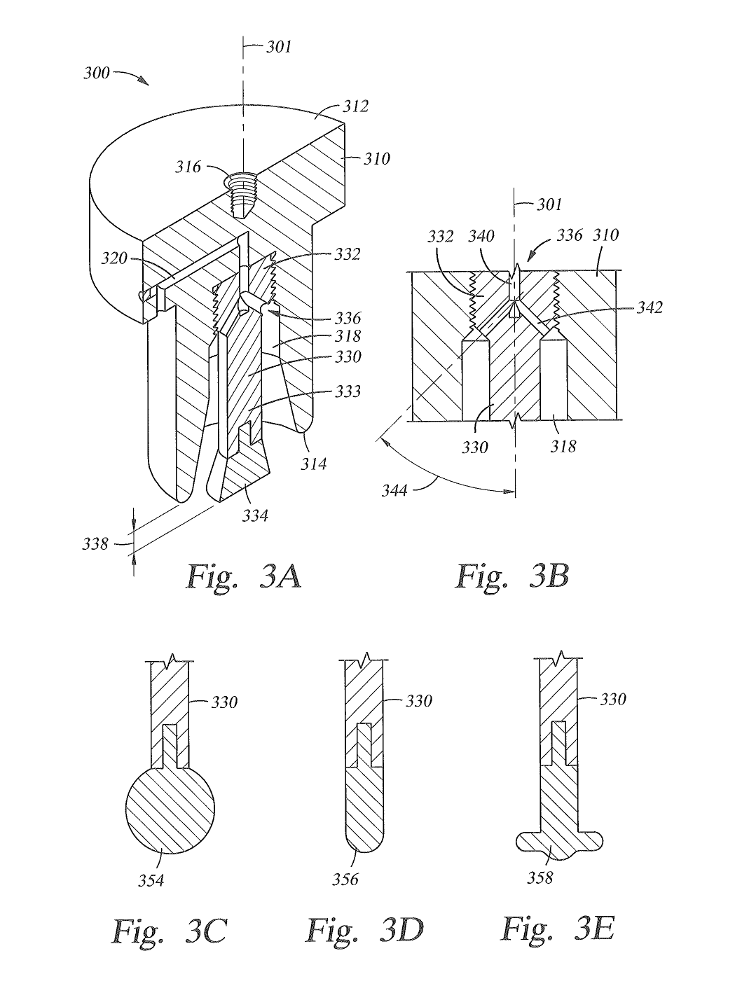

FIG. 3A is a schematic perspective view of a hollow cathode assembly 300 according to one embodiment of the present invention. The hollow cathode assembly 300 may be used as the hollow cathode assembly 112 in the plasma processing chamber 100 of FIG. 1.

The hollow cathode assembly 300 may include a conductive body 310 having an upper side 312 and a lower side 314. An inner volume 318 is formed in the conductive body 310. The inner volume 318 is a blind recess that opens at the lower side 314. The inner volume 318 may be expanding towards the lower side 314. The conductive body 310 may be formed as unitary body or assembled from two or more conductive components.

The conductive body 310 and the inner volume 318 are symmetric about a central axis 301. An RF adapting structure 316 may be formed on the upper side 312 of the conductive body 310. The RF adapting structure 316 is adapted to receive a RF cable connecting the hollow cathode assembly 300 to a RF power source so that the hollow cathode assembly 300 can be RF hot for plasma ignition. A gas channel 320 may be formed in the conductive body 310 so that one or more processing gas may be delivered to the inner volume 318.

The hollow cathode assembly 300 further includes a central rod 330 at least partially disposed in the inner volume 318 along the central axis 301. The central rod 330 is also symmetrical about the central axis 301. The central rod 330 is formed from a conductive material. An upper end 332 of the central rod 330 is coupled to the conductive body 310 inside the inner volume 318. The central rod 330 may be joined to the conductive body 310 by suitable methods so that the central rod 330 and the conductive body 310 are electrically connected. In one embodiment, the central rod 330 may be joined to the conductive body 310 by a threaded joint.

The conductive tip 334 is connected to a lower end 333 of the central rod 330. Alternatively, the conductive tip 334 and the central rod 330 may be formed from a continuous single mass material. The conductive tip 334 extends beyond the lower side 314 of the conductive body 310 so that the plasma ignites from the conductive tip 334. The conductive tip 334 may extend beyond the lower side 314 by a distance 338. The distance 338 may be chosen according to process requirements.

In one embodiment, a gas nozzle 336 may be formed in the upper end 332 of the central rod 330. FIG. 3B is an enlarged partial sectional view of the hollow cathode assembly 300 showing details of the gas nozzle 336. The gas nozzle 336 may include an inlet channel 340 connected to a plurality of gas outlets 342. The inlet channel 340 is positioned to connect with the gas channel 320 formed in the conductive body 310. In one embodiment, the inlet channel 340 may be formed on the central axis 301 and each of the plurality of gas outlets 342 runs radially outwards from the central axis 301. As shown in FIG. 3B, each of the plurality of gas outlets 342 may be tilted at an angle 344 from the central axis 301. In one embodiment, the angle 344 may be about 45°. The plurality of gas outlets 342 may be evenly distributed about the central axis 301 so that the one or more processing gas may be delivered uniformly and symmetrically about the central rod 330 to the inner volume 318. In one embodiment, the gas nozzle 336 may include six gas outlets 342 arranged 60° apart.

The shapes and/or dimensions of the conductive tip 334 may be chosen according process requirements. In one embodiment, conductive tips having different shapes and/or sizes may be interchangeably attached to the central rod 330 according to process requirements, for example via a detachable tip of the rod 330. The conductive tip 334 of FIG. 3A has a cone shaped tip. Conductive tips with different shapes are shown in FIGS. 3C-3E. In FIG. 3C, a ball shaped conductive tip 354 is attached to the central rod 330. In FIG. 3D, a semi sphere shaped conductive tip 356 is attached to the central rod 330. In FIG. 3E, a disk shaped conductive tip 358 is attached to the central rod 330.

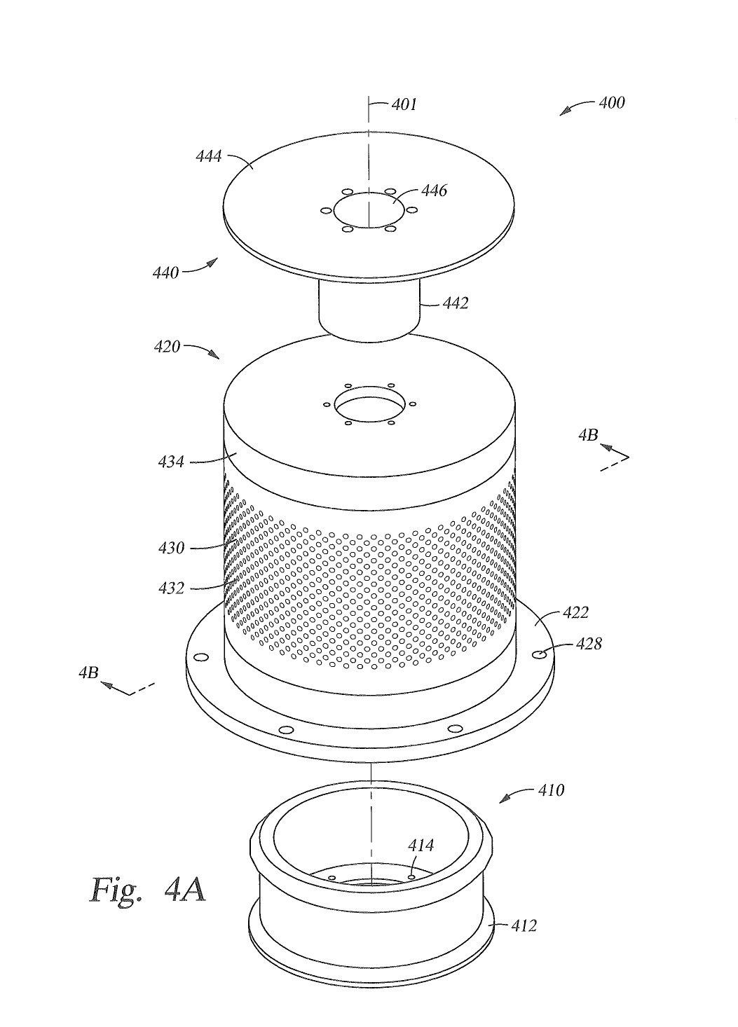

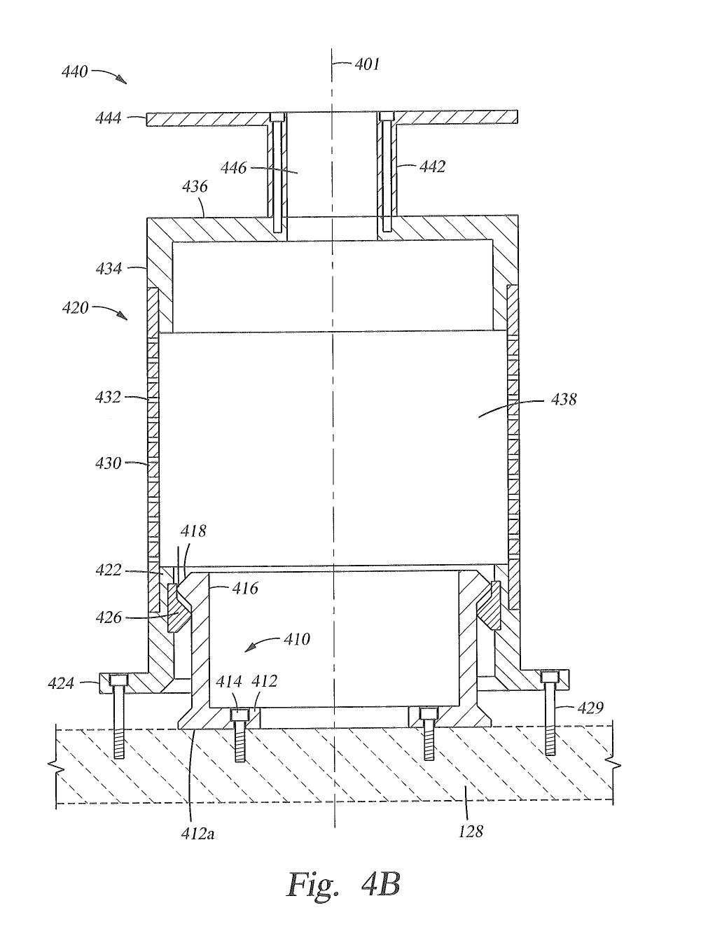

FIG. 4A is a perspective view of a RF return shield assembly 400 according to one embodiment of the present invention. FIG. 4B is a partial sectional view of the RF return shield assembly 400. The RF return shield assembly 400 may be used in a plasma processing chamber to provide return path between the plasma to the RF ground and shield RF hot components. The RF return shield assembly 400 may include a contact ring 410, a cylindrical shield 420 and an upper shield 440. The RF return shield assembly 400 is symmetrical about a central axis 401 to provide a uniform and symmetric RF return path.

The contact ring 410 is configured to be in electrical contact with a ground electrode, such as the ground electrode 128 shown in FIG. 4B. In one embodiment, the contact ring 410 may include a contact flange 412 having a planar surface 412a for establishing solid contact with the ground electrode 128. The contact flange 412 may have two or more screw holes 414 for attaching the contact ring 410 and the ground electrode 128. A connection tube 416 may extend upwards from the contact flange 412. The connection tube 416 has a connection tip 418 protruding radially outward for establishing electrical connection with the circular shield 420. The connection tip 418 may have an annular form or a plurality of tips 418 may be symmetrically distributed around the connection tube 416.

The circular shield 420 forms a closed loop for providing a uniform RF return path. The circular shield 420 also encloses an inner volume 438 for receiving a hollow cathode assembly therein. The circular shield 420 may include a lower ring 422, an upper ring 434 and a perforated tube 430 having openings 432 connected in between. The lower ring 422 may have an alignment flange 424. The circular shield 420 may be aligned with the contact ring 410 by threading screws through two more alignment holes 428 into the ground electrode 128. When installed, a gap 429 may be present between the lower ring 422 and the ground electrode to provide tolerance of structure deformation, such as deformation caused by thermal expansion. The lower ring 422 may include a connection spring 426 biased against the contact ring 410 to establish RF connection between the lower ring 422 and the contact ring 410. The upper ring 434 may include a cover 436. The upper shield 440 is attached to the cover 436.

The upper shield 440 may include a tube 442 surrounding an inner volume 446 and a flange 444. The inner volume 446 may enclose a RF connection to the electrode in the disposed in the inner volume 438. The flange 444 is configured to connect with a RF ground of a RF power source.

Even though, cylindrical RF ground shields are discussed above, other symmetrical shapes, such as hexagon, octagon, or other polygon shapes.

Hollow cathode assemblies may also have two or more hollow cathode sections. Each of the two or more hollow cathode sections may be powered individually, for examples, by providing different power to each of the two or more hollow cathode sections. Processing gas can also be delivered separately to each of the two or more hollow cathode sections, for example, by providing one or more different gas or gas mixtures to one hollow cathode section relative to another. By using two or more hollow cathode sections, non-uniformity and non-symmetry caused by the dimension difference between a hollow cathode and the opposing ground electrode may be over compensated by providing power and/gas(es) to different hollow cathode sections to tune out the asymmetries. In one embodiment, the two or more hollow cathode sections may be arranged in a concentric manner. Alternatively, the two or more hollow cathode sections may have the same dimension and arranged in a symmetric manner.

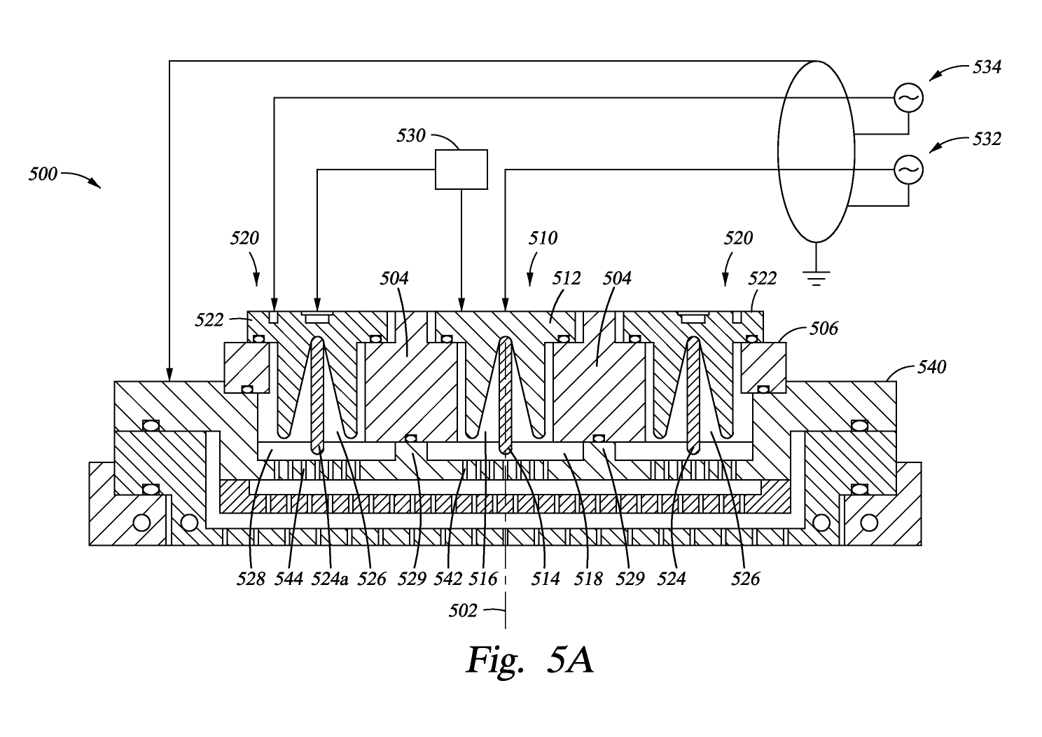

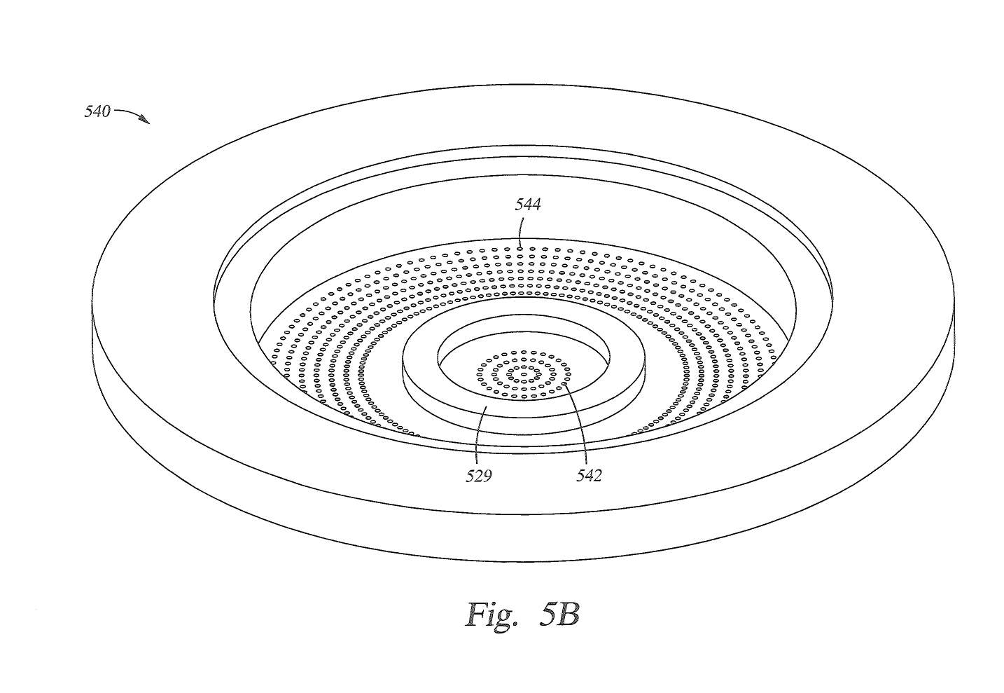

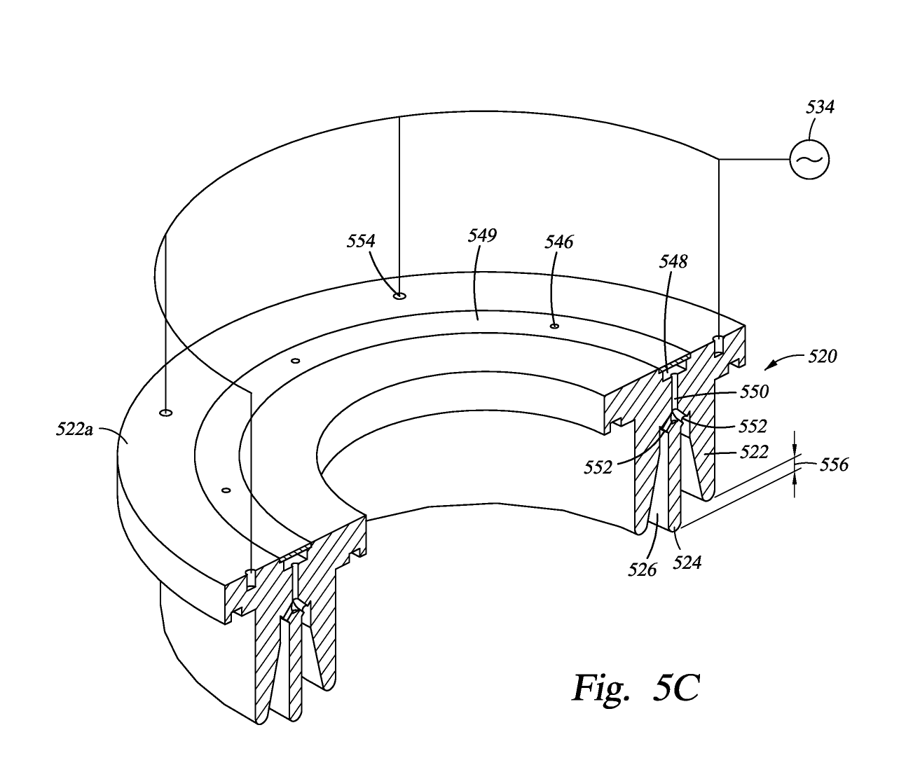

FIG. 5A is a schematic sectional side view of a hollow cathode assembly 500 according to one embodiment of the present invention. The hollow cathode assembly 500 includes two or more hollow cathode sections that can be powered independently, that is, different power applied to different hollow cathode sections.

The hollow cathode assembly 500 is symmetric about a central axis 502 for generating uniform and symmetrical plasma. The hollow cathode assembly 500 includes an inner section 510 and an outer section 520 concentrically disposed outside the inner section 510. Both the inner section 510 and outer section 520 are symmetric about the central axis 502. An isolator 504 is disposed between the inner section 510 and the outer section 520 so that the inner section 510 and the outer section 520 can be powered independently. The hollow cathode assembly 500 further includes a ground electrode 540 and an isolator 506 disposed between the ground electrode 540 and the isolator 506.

Similar to the hollow cathode assemblies 112, 200, and 300 described above, the inner section 510 includes a conductive body 512 which defines an inner volume 516 for plasma generation. A central rod 514 is coupled to the conductive body 512 in and extends beyond the inner volume 516 for plasma ignition.

The outer section 520 includes a conductive body 522. The outer conductive body 522 is a ring shape and concentrically disposed outward from the inner section 510. The conductive body 522 defines a ring-shaped inner volume 526. A central tube 526 is coupled to the conductive body 522 and extends through the inner volume 526. The central tube 526 is formed from a conductive material and may have a cylindrical form. The central tube 526 may extend beyond the inner volume 526 toward the ground electrode 540. A lower end 524a of the central tube 526 is positioned closest to the ground electrode 540 and becomes the point of plasma ignition during operation.

A gas source 530 may be independently connected to the inner section 510 and the outer section 520. Accordingly, the type and amount of processing gas(es) delivered to the inner volume 516 and inner volume 526 may be adjusted independently. Similarly, the inner section 510 and the outer section 520 may be powered independently. As shown in FIG. 5A, a first RF power source 532 is coupled to the inner section 510 and a second RF power source 534 is coupled to the outer section 520 so that different amount of power may be applied to the sections 510, 520. Alternatively, a single RF power source may be connected to both the inner section 510 and the outer section 520 by a switch.

The ground electrode 540 may be a disk shaped conductive body having a first opening section 542 facing the inner section 510 and a second opening section 544 facing the outer section 520. The ground electrode 540 may have an inner wall 529 separating the first opening section 542 and the second opening section 544. The isolator 504 may be sealing attached to the inner wall 529 forming an inner plasma cavity 518 between the inner section 510 and ground electrode 540 and an outer plasma cavity 528 between the outer section 520 and the ground electrode 540. The inner plasma cavity 518 and the outer plasma cavity 528 may be isolated from each other to prevent gas mixing.

FIG. 5B is a schematic perspective view of the ground electrode 540. As shown in FIG. 5B, the first opening section 542 and the second opening section 544 may be concentric.

FIG. 5C is a schematic perspective sectional view of the outer section 520 of the hollow cathode assembly 500. A gas channel 548 may be formed on an upper side 522a of the conductive body 522. The gas channel 548 may be defined by a circular grove covered by a lid 549. A plurality of inlets 546 may be formed through the lid 549 for receiving one or more processing gas from a gas source. A plurality of distribution channels 550 may be formed in the conductive body 522 in connection with the gas channel 548. Each distribution channel 550 may be connected to two outlets 552 opening at opposite sides of the central tube 524 to evenly distribute the processing gas to the inner volume 526. In one embodiment, a plurality of RF adapting structures 554 may be formed on the upper side of the conductive body 522. The plurality of RF adapting structures 554 may be evenly distributed along the conductive body 522 to provide uniform and symmetrical RF power supply.

Even though only two hollow cathode sections are shown in the hollow cathode assembly 500, additional hollow cathode sections may be added to the hollow cathode assembly 500, for example more cathode sections may be added radially outward of the outer section 520 and concentric with both the inner section 510 and the outer section 520.

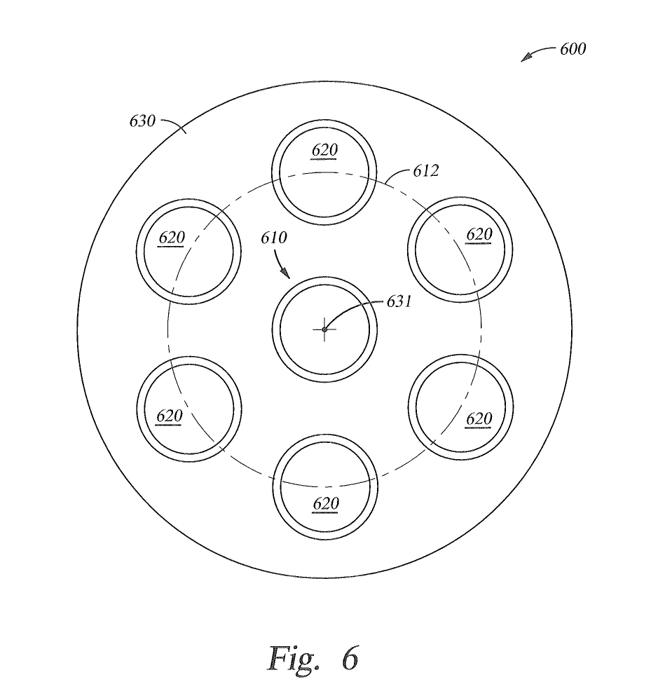

FIG. 6 is a schematic top view of a hollow cathode assembly 600 according to another embodiment of the present invention. The hollow cathode assembly 600 includes a plurality of identical hollow cathodes 610, 620 evenly distributed across a processing area 630 defined by a chamber body. In the embodiment of FIG. 6, the processing area 630 is cylindrical having a central hollow cathode 610 disposed in a center 631 of the processing area 630 and a plurality of outer hollow cathodes 620 disposed along an imaginary circle 612 having a center at the center 631. The hollow cathodes 610, 620 may be similar or identical in structure, such as similar to the hollow cathode assemblies 112, 200, 300, but positioned across the processing area 630 to provide uniform and/or symmetrical plasma distribution. For processing areas of non-circular shapes, such as rectangular processing areas utilized for processing display panels, solar panels and the like, the plurality hollow cathodes arranged in a Cartesian (grid) array for promoting uniform and symmetrical plasma processing conditions within the processing chamber.

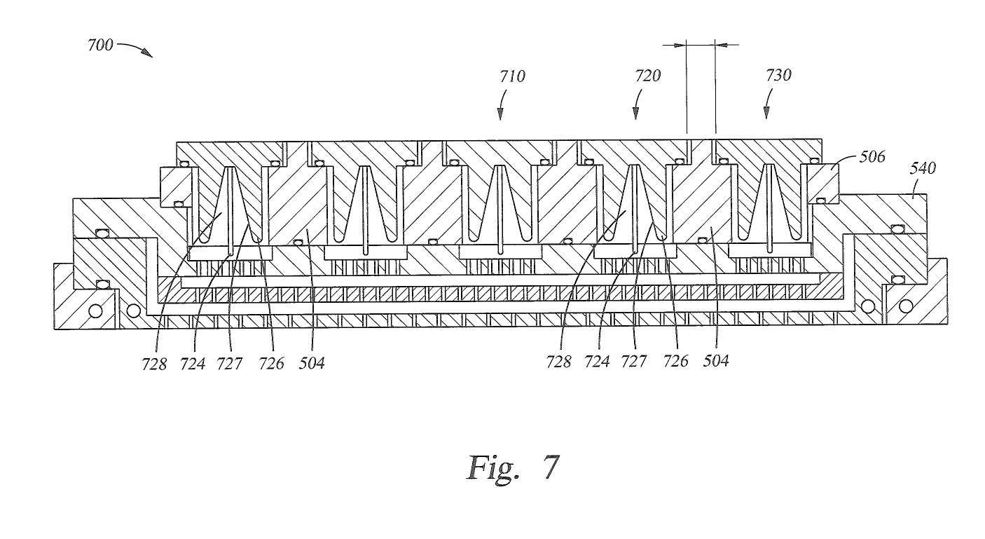

FIG. 7 is a schematic sectional side view of an alternative hollow cathode assembly 700. The hollow cathode assembly 700 is similar to the hollow cathode assembly 600 except outer sections 720, 730 have a different shape compared to the inner section. The hollow cathode assembly 700 includes a central section 710, a middle section 720, and an outer section 730 disposed concentrically with one another. The middle section 720 includes a conductive body 722. The conductive body 722 may have circular walls 726 that taper towards a distal end of the circular walls 726. An inner surface 727 is slanted enclosing an expanding volume 728. Optionally, an ignition tube 724, similar or identical to the ignition tube 514, may extend from the conductive body 722 from the inner wall 725 for plasma ignition. The outer section 730 is similar to the middle section 720 with larger diameter.

Each of the hollow cathode assemblies may have a RF ground shield such as the RF ground shield assembly 400 shown in FIGS. 4A-4B.

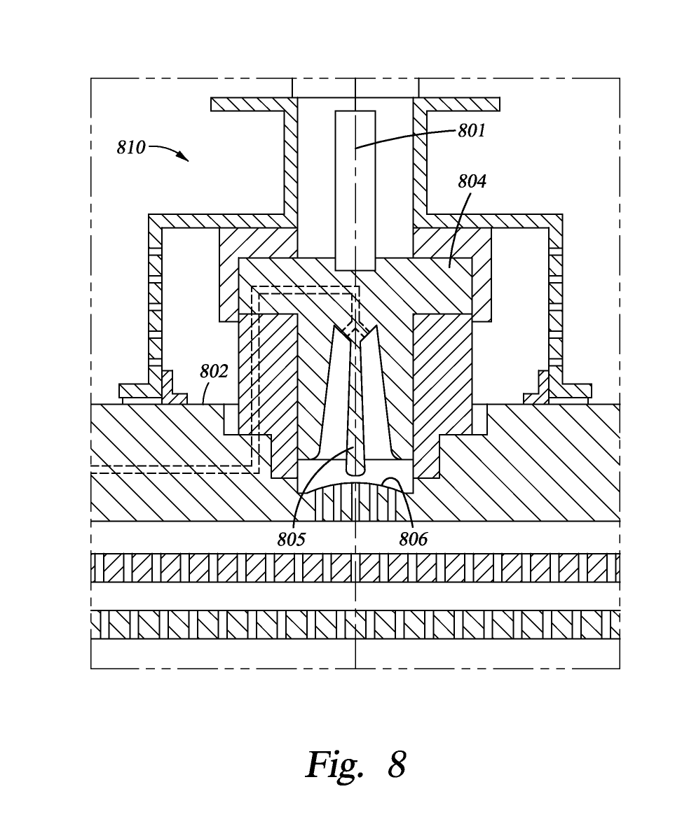

FIG. 8 is a schematic sectional side view of a hollow cathode assembly 810 according to another embodiment of the present invention. The hollow cathode assembly 810 is similar to the hollow cathode plasma source 110 of FIG. 1 except the hollow cathode assembly 810 includes a ground electrode 802 having a convex upper surface 806 facing a hollow cathode assembly 804. The convex upper surface 806 has a highest point on a central axis 801 of the hollow cathode assembly 804 so that the shortest distance between the convex upper surface 806 and the hollow cathode assembly 804 is on the central axis 801 to ensure plasma ignites at a point on the central axis 801, thus being symmetrical about the central axis. The ground electrode 802 may be used alone or in combination with a central rod 805 to achieve symmetry.

Hollow cathode assemblies of the present invention may be used to any suitable plasma processes. In one embodiment, the hollow cathode assemblies may be used to perform a dry etch process for removing silicon oxide using an ammonia (NH₃) and nitrogen trifluoride (NF₃) gas mixture.

While the foregoing is directed to embodiments of the present invention, other and further embodiments of the invention may be devised without departing from the basic scope thereof, and the scope thereof is determined by the claims that follow.

1. An electrode for generating a plasma, comprising:
a conductive body having an upper side, a lower side, and a central volume open at the lower side, wherein the conductive body and the central volume is substantially symmetric about a central axis extending from the upper side to the lower side, and a gas channel is formed through the conductive body and open to the central volume; and
a conductive rod positioned in the central volume on the central axis, wherein a first end of the conductive rod is coupled to the conductive body and a second end extends out of the central volume beyond the lower side.

2. The electrode of claim 1, further comprising an RF connector coupled to the upper side of the conductive body, wherein the RF connector positioned along the central axis.

3. The electrode of claim 2, wherein the central volume is a flared volume that expands at the lower side.

4. The electrode of claim 1, wherein the second end of the conductive rod is a cone shaped, disk shaped or a spherical shaped tip.

5. The electrode of claim 1, wherein the conductive rod comprises a main body and an end section attached to the main body, and the end section is a cone shaped, disk shaped or a spherical shaped tip.

6. The electrode of claim 1, wherein the gas channel includes a plurality of outlets distributed around the first end of the conductive rod.

7. The electrode of claim 1, wherein the conductive body comprises:
a disk shaped upper portion; and
a hollow lower portion attached to a lower surface of the disk shaped upper portion, wherein the central volume is formed defined by the lower surface of the disk shaped upper body and an inner surface of the hollow lower portion.

8. The electrode of claim 1, further comprising:
an outer conductive body disposed around the conductive body; and
an isolator disposed between the conductive body and the outer conductive body, wherein the outer conductive body and the conductive body are concentrically arranged.

9. The electrode of claim 8, further comprising:
a conductive tube disposed in an inner volume of the outer conductive body.

10. The electrode of claim 1, further comprising:
a plurality of outer conductive bodies disposed in around the conductive body in symmetrically manner.

11. A hollow cathode plasma source, comprising:
a first electrode comprising:
a conductive body having an upper side, a lower side, and a central volume open at the lower side, wherein the conductive body and the central volume are substantially symmetric about a central axis extending from the upper side to the lower side, and the conductive body has a gas channel open to the central volume; and
a conductive rod positioned in the central volume on the central axis, wherein a first end of the conductive rod is coupled to the conductive body and a second end extends out of the central volume beyond the lower side;
a second electrode facing the lower side of the first electrode, wherein the second electrode includes a plurality of through holes in fluid connection with the central opening of the first electrode; and
an RF isolator disposed between the first electrode and second electrode.

12. The hollow cathode source of claim 11, wherein the first electrode further comprises an RF connector coupled to the upper side of the conductive body, and the RF connector positioned along the central axis.

13. The hollow cathode plasma source of claim 12, further comprising:
an RF return shield secured to an upper surface of the second electrode and extending upward from the second electrode to enclose the first electrode therein.

14. The hollow cathode plasma source of claim 13, wherein the RF return shield comprises:
a contact ring attached to the upper surface of the second electrode radially outward from the first electrode;
a tube in electrical contact with the contact ring, wherein the tube encloses but is not in contact with the first electrode.

15. The hollow cathode plasma source of claim 14, further comprising:
a connector spring electrically coupling the tube and the contact ring.

16. The hollow cathode plasma source of claim 11, wherein the first electrode further comprises:
an outer conductive body concentrically disposed around the conductive body; and
an isolator disposed between the conductive body and the outer conductive body, wherein the outer conductive body and the conductive body are concentrically arranged.

17. The hollow cathode plasma source of claim 11, wherein the first electrode further comprises a plurality of outer conductive bodies disposed in around the conductive body in symmetrically manner.

18. An apparatus for processing semiconductor substrate, comprising:
a chamber body defining an inner volume;
a hollow cathode plasma source disposed above the inner volume, wherein the hollow cathode plasma source comprises:
a first electrode comprising:
a conductive body having an upper side, a lower side, and a central volume open at the lower side, wherein the conductive body and the central volume is substantially symmetric about a central axis extending from the upper side to the lower side, and a gas channel is formed in the conductive body and open to the central volume; and
a conductive rod at least partially disposed in the central volume along the central axis, wherein a first end of the conductive rod is coupled to the conductive body and a second end extends out of the central volume beyond the lower side;
a second electrode facing the lower side of the first electrode, wherein the second electrode includes a plurality of through holes in fluid connection with the central opening of the first electrode; and
an RF isolator disposed between the first electrode and second electrode; and
a substrate support assembly disposed below the hollow cathode plasma source.

19. The apparatus of claim 18, further comprising an RF return shield secured to an upper surface of the second electrode and extending upward from the second electrode to enclose the first electrode therein, wherein the RF return shield comprises:
a contact ring attached to the upper surface of the second electrode radially outward from the first electrode;
a tube in electrical contact with the contact ring, wherein the tube encloses but is not in contact with the first electrode, and at least a portion of the tube is perforated.

20. The apparatus of claim 18 wherein the first electrode further comprises:
an outer conductive body concentrically disposed around the conductive body; and
an isolator disposed between the conductive body and the outer conductive body, wherein the outer conductive body and the conductive body are concentrically arranged.
